(19) United States
(12) Patent Application Publication
(10) Pub. No.: US 2026/0354107 A1
(43) Pub. Date: Nov. 5, 2026

(54) CARRIER SUBSTRATE AND MANUFACTURING METHOD OF SEMICONDUCTOR DEVICE USING THE SAME

(71) Applicant: SAMSUNG ELECTRONICS CO., LTD., Suwon-si (KR)

(72) Inventor: Ju Yeob LEE, Suwon-si (KR)

(73) Assignee: SAMSUNG ELECTRONICS CO., LTD., Suwon-si (KR)

(21) Appl. No.: 19/467,363

(22) Filed: Feb. 2, 2026

(30) Foreign Application Priority Data
Apr. 30, 2025 (KR) 10-2025-0057414

(51) Int. Cl. H10P 72/70

(52) U.S. Cl. CPC H10P 72/7412; H10P 72/7438; H10P 72/744

(57) ABSTRACT

There is provided a carrier substrate and a manufacturing method of a semiconductor device using the same, the carrier substrate including a base layer, a buffer layer on the base layer, a debonding layer on the buffer layer and comprising a metal, and a capping layer on the debonding layer and in contact with an upper surface of the base layer, wherein the debonding layer is surrounded by the base layer and the capping layer, and an oxygen transmission rate (OTR) of the buffer layer is greater than an OTR of the capping layer.

### CROSS-REFERENCE TO RELATED APPLICATION

This application is based on and claims priority from Korean Patent Application No. 10-2025-0057414 filed on Apr. 30, 2025 in the Korean Intellectual Property Office and all the benefits accruing therefrom under 35 U.S.C. 119, the contents of which in its entirety are herein incorporated by reference.

### BACKGROUND

### Field

The present disclosure is related to a carrier substrate and a manufacturing method of a semiconductor device using the same.

### Description of Related Art

In recent years, with the trend of high integration and thinning of semiconductor packaging technology, the role of a carrier substrate that temporarily supports a semiconductor device during a manufacturing process has become important. The carrier substrate is attached to the semiconductor device, and after the semiconductor package manufacturing process is performed together with the semiconductor device, it is debonded from the semiconductor device.

A silicon wafer is generally used as such a carrier substrate, and the silicon substrate has multiple advantages, including excellent heat resistance characteristics, reduced warpage due to high elastic modulus, and economical cost.

When the silicon wafer is used as the carrier substrate, the semiconductor device is attached to the silicon wafer using an adhesive layer, and the carrier substrate is mechanically debonded from the semiconductor device by inserting a blade into the adhesive layer. In such a mechanical debonding manner, as the adhesive force of the adhesive layer is relatively great, the greater stress may be applied to the semiconductor device when debonding, which may cause damage to the semiconductor device.

As an alternative to this, a method of using a glass substrate as the carrier substrate has been proposed. When the glass substrate is used as the carrier substrate, the semiconductor device is attached to the glass substrate using an ultraviolet tape, and the carrier substrate is debonded from the semiconductor device by decomposing the ultraviolet tape using ultraviolet light. Such a chemical debonding manner applies little stress to the semiconductor device when debonding. However, because the ultraviolet tape is vulnerable to high temperature fixation due to low heat resistance characteristics, the adhesive force between the carrier substrate and the semiconductor device may weaken during the manufacturing process of the semiconductor package, and an expensive glass substrate needs to be used as the carrier substrate.

### SUMMARY

One or more embodiments of the present disclosure may provide a carrier substrate that is economical in terms of manufacturing costs, while effectively reducing the mechanical stress applied to the semiconductor device in or during the debonding process.

One or more embodiments of the present disclosure may provide a method for manufacturing a semiconductor device using a carrier substrate that is economical in terms of manufacturing costs, while effectively reducing the mechanical stress applied to the semiconductor device in the debonding process.

One or more embodiments of the present disclosure may provide a method for manufacturing a carrier substrate that is economical in terms of manufacturing costs, while effectively reducing the mechanical stress applied to the semiconductor device in the debonding process.

One or more embodiments of the present disclosure may provide a carrier substrate including, a base layer, a buffer layer on the base layer, a debonding layer on the buffer layer and comprising a metal, and a capping layer on the debonding layer and in contact with an upper surface of the base layer, wherein an oxygen transmission rate (OTR) of the buffer layer is greater than an OTR of the capping layer. The debonding layer may be surrounded by the base layer and the capping layer.

One or more embodiments of the present disclosure may provide a base layer including single crystal silicon (Si), an organic layer on the base layer and having an oxygen transmission rate (OTR) of 20 cc/m²·day or more, a metal layer on the organic layer and having a Pilling-Bedworth ratio (PBR) of 1.2 or more, and a capping layer on the metal layer and including a first capping layer in contact with an upper surface of the base layer and a side wall of the metal layer, and a second capping layer on the first capping layer, wherein an oxygen transmission rate of the capping layer is 10⁻² cc/m²·day or less, and an oxygen permeability (OP) of a material included in the first capping layer is different from an oxygen permeability of a material included in the second capping layer. The metal layer may be surrounded by the base layer and the capping layer.

One or more embodiments of the present disclosure may provide a method for manufacturing a semiconductor device, the method including, providing a carrier substrate including a base layer, a buffer layer on the base layer, a debonding layer on the buffer layer and comprising a metal, and a capping layer on the debonding layer and in contact with an upper surface of the base layer, wherein the debonding layer is surrounded by the base layer and the capping layer, and an oxygen transmission rate (OTR) of the buffer layer is greater than an OTR of the capping layer, attaching a semiconductor device onto the carrier substrate, cutting a part of the capping layer to expose the debonding layer to an external environment , and separating the debonding layer and the buffer layer to debond the semiconductor device from the carrier substrate.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail example embodiments thereof with reference to the attached drawings, in which:

FIG. 1 is a plan view for explaining a carrier substrate according to one or more embodiments.

FIG. 2 is a cross-sectional view taken along A-A’ of FIG. 1.

FIG. 3 is an enlarged view of a region P of FIG. 2.

FIGS. 4 - 5 are diagrams for explaining a carrier substrate according to one or more embodiments.

FIG. 6 is a diagram for explaining a carrier substrate according to one or more embodiments.

FIG. 7 is a diagram for explaining a carrier substrate according to one or more embodiments.

FIG. 8 is a flowchart for explaining a method for manufacturing a semiconductor device using a carrier substrate according to one or more embodiments.

FIGS. 9 - 16 are intermediate step diagrams for explaining the method for manufacturing the semiconductor device using the carrier substrate of FIG. 8.

FIG. 17 is a flowchart for explaining the method for manufacturing the carrier substrate according to some embodiments.

FIGS. 18 - 21 are intermediate step diagrams for explaining the method for manufacturing the carrier substrate of FIG. 17.

### DETAILED DESCRIPTION OF EMBODIMENTS

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

When an element is said to be “connected”, “coupled”, “supported”, or “contacted” to, with, or by another element, this includes not only when elements are directly connected, coupled, supported or contacted, but also when elements are indirectly connected, coupled, supported or contacted through a third element.

In addition, in the present disclosure, the meaning of “identical” includes cases where properties are similar to each other or similar within a certain range. Furthermore, identical means “substantially identical”. The meaning of substantially identical should be understood to include numerical values within manufacturing error ranges or differences within a range that is insignificant with respect to a reference numerical value as falling within the scope of ‘identical’.

As used herein, the terms “front (or forward)”, “rear (or back, rearward)”, “left”, “right”, “up (or top)”, “down (or bottom)” and the like may be defined with reference to the drawings, and may not be intended to limit the shape and position of each component.

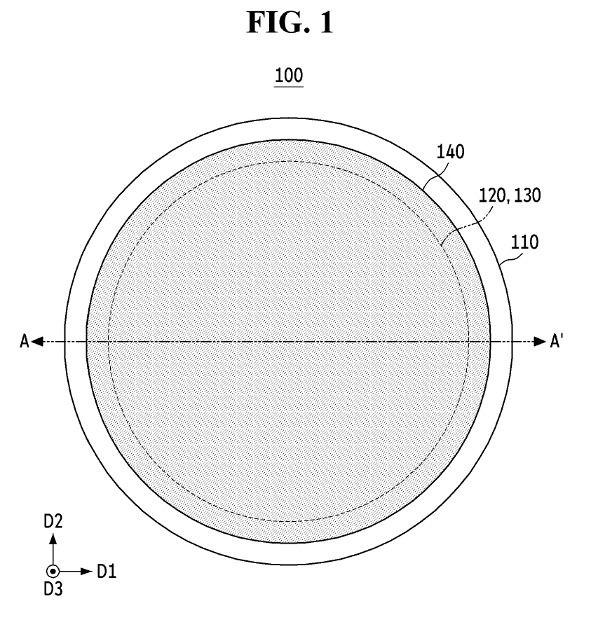

Hereinafter, embodiments of a carrier substrate according to the present disclosure will be described referring to FIGS. 1 - 7.

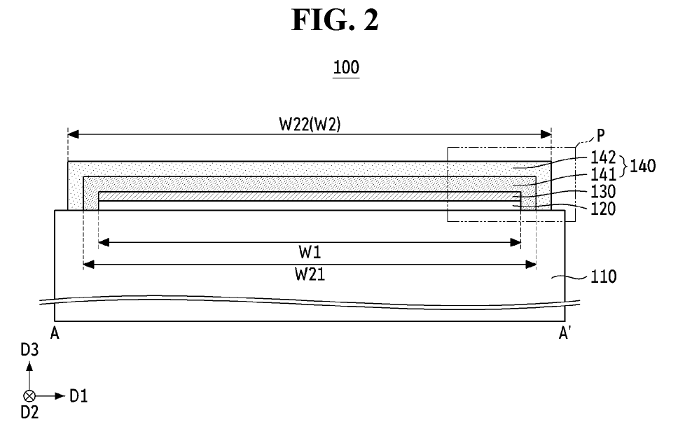

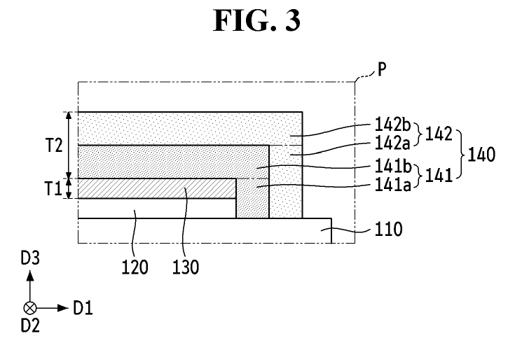

FIG. 1 is a plan view for explaining a carrier substrate according to some embodiments. FIG. 2 is a cross-sectional view taken along A-A’ of FIG. 1. FIG. 3 is an enlarged view of a region P of FIG. 2.

Referring to FIGS. 1 - 3, a carrier substrate 100 according to some embodiments comprises a base layer 110, a buffer layer 120, a debonding layer 130, and a capping layer 140.

The base layer 110 may have a disk shape. The base layer 110 may have widths in a first direction D1 and a second direction D2. The first direction D1 and the second direction D2 may be directions that intersect each other and are parallel to an upper surface of the base layer 110. A width of the base layer 110 in the first direction D1 and a width of the base layer 110 in the second direction D2 may each be diameters of the base layer 110.

The base layer 110 may have a thickness in a third direction D3. The third direction D3 may be a direction perpendicular to the upper surface of the base layer 110. The third direction D3 may be perpendicular to the first direction D1 and the second direction D2. The thickness of the base layer 110 may be smaller than the width of the base layer 110 in the first direction D1.

The base layer 110 may be a silicon wafer. The base layer 110 may include single crystal silicon (i.e., “bulk”, “monocrystalline”, or “monolithic” silicon), but the material of the base layer 110 is not particularly limited thereto.

The buffer layer (organic layer) 120 may be disposed on the base layer 110. The buffer layer 120 may cover at least a portion of the upper surface of the base layer 110. The buffer layer 120 may cover the upper surface of the base layer 110 except for an edge thereof. The width of the buffer layer 120 in the first direction D1 may be smaller than the width of the base layer 110 in the first direction D1. The buffer layer 120 may be in contact with the upper surface of the base layer 110. The thickness of the buffer layer 120 in the third direction D3 may be smaller than the width of the buffer layer 120 in the first direction D1.

The buffer layer 120 may have a high oxygen transmission rate (OTR) and a high water vapor transmission rate (WVTR). The oxygen transmission rate of the buffer layer 120 may be 1 cc/m²·day or more, and the water vapor transmission rate of the buffer layer 120 may be 1 g/m²·day or more. More preferably, the oxygen transmission rate of the buffer layer 120 may be 20 cc/m²·day or more and 1000 cc/m²·day or less, and the water vapor transmission rate of the buffer layer 120 may be 10 g/m²·day or more and 1000 g/m²·day or less.

The oxygen transmission rate and the water vapor transmission rate of the buffer layer 120 may be directly measured, using a measuring device. Alternatively, the oxygen transmission rate and the water vapor transmission rate of the buffer layer 120 may be calculated, using an oxygen permeability (OP) and a water vapor permeability (WVP) of a material included in the buffer layer 120, and the thickness of the buffer layer 120. The oxygen transmission rate and water vapor transmission rate of the buffer layer 120, and the oxygen permeability and water vapor permeability of the material included in the buffer layer 120 may be values that are measured or calculated under atmospheric pressure and room temperature conditions.

The buffer layer 120 may include an organic material. The buffer layer 120 may include an organic material containing a metal element.

The debonding layer (metal layer) 130 may be disposed on the buffer layer 120. The buffer layer 120 may be disposed between the base layer 110 and the debonding layer 130. The debonding layer 130 may cover the upper surface of the buffer layer 120.

The debonding layer 130 may be in contact with the upper surface of the buffer layer 120. Alternatively, the buffer layer 120 may be in contact with a bottom surface of the debonding layer 130. An adhesive force between the buffer layer 120 and the debonding layer 130 may be low. A shear adhesion strength between the buffer layer 120 and the debonding layer 130 may be 1 MPa or less and 0.001 MPa or more.

The debonding layer 130 may include a metal. The debonding layer 130 may include a metal that increases in volume when oxidized. The debonding layer 130 may include a metal with a Pilling-Bedworth ratio (PBR) of 1.2 or more and 10 or less. The Pilling-Bedworth ratio (PBR) refers to a ratio of a volume of an oxide formed from the metal to the volume of the metal. The debonding layer 130 may include, for example, at least one of aluminum (Al), lead (Pb), chromium (Cr), nickel (Ni), cobalt (Co), iron (Fe), titanium (Ti), zirconium (Zr), uranium (U) or hafnium (Hf). However, the technical idea of the present disclosure is not limited thereto.

The capping layer 140 may be disposed on the base layer 110, the buffer layer 120 and the debonding layer 130. The capping layer 140 may extend along the upper surface of the base layer 110, the side wall of the buffer layer 120 and the side wall and upper surface of the debonding layer 130. The debonding layer 130 may be disposed between the buffer layer 120 and the capping layer 140.

The capping layer 140 may cover the upper surface and side wall of the debonding layer 130. The capping layer 140 may be in contact with the upper surface and side wall of the debonding layer 130. The capping layer 140 may cover the side wall of the buffer layer 120. The capping layer 140 may be in contact with the side wall of the buffer layer 120. The capping layer 140 may be in contact with the upper surface of the base layer 110.

The debonding layer 130 may be surrounded by the base layer 110 and the capping layer 140. The buffer layer 120 may be surrounded by the base layer 110, the debonding layer 130, and the capping layer 140.

A width W2 of the capping layer 140 in the first direction D1 may be smaller than a width of the base layer 110 in the first direction D1. The width W2 of the capping layer 140 in the first direction D1 may be larger than a width of the buffer layer 120 in the first direction D1. A width W2 of the capping layer 140 in the first direction D1 may be larger than the width W1 of the debonding layer 130 in the first direction D1.

A thickness T2 of the capping layer 140 in the third direction D3 may be larger than the sum of a thickness of the buffer layer 120 in the third direction D3 and a thickness T1 of the debonding layer 130 in the third direction D3. The thickness T2 of the capping layer 140 may be equal to a distance from the upper surface of the debonding layer 130 to the upper surface of the capping layer 140 in the third direction D3.

The thickness of the base layer 110 may be greater than the sum of the thickness of the buffer layer 120, the thickness T1 of the debonding layer 130, and the thickness T2 of the capping layer 140.

The capping layer 140 may have low oxygen transmission rate and low water vapor transmission rate. The oxygen transmission rate of the capping layer 140 may be less than 1 cc/m^{2·}day, and the water vapor transmission rate of the capping layer 140 may be less than 1 g/m^{2·}day. More preferably, the oxygen transmission rate of the capping layer 140 may be 10⁻² cc/m²·day or less and 10⁻²⁰ cc/m²·day or more, and the water vapor transmission rate of the capping layer 140 may be 10⁻² g/m²·day or less and 10⁻²⁰ g/m²·day or more.

The capping layer 140 may surround the buffer layer 120 and the debonding layer 130 and may have low oxygen transmission rate and low water vapor transmission rate, thereby blocking the buffer layer 120 and the debonding layer 130 from reacting with external oxygen and water vapor.

The oxygen transmission rate and water vapor transmission rate of the capping layer 140 may be directly measured using a measuring device. Alternatively, the oxygen transmission rate and water vapor transmission rate of the capping layer 140 may be calculated using the oxygen permeability and water vapor permeability of the material forming the capping layer 140 and the thickness of the capping layer 140. The oxygen transmission rate and water vapor transmission rate of the capping layer 140, and the oxygen permeability and water vapor permeability of the material forming the capping layer 140 may be values that are measured or calculated under atmospheric pressure and room temperature conditions.

The oxygen transmission rate of the capping layer 140 may be lower than the oxygen transmission rate of the buffer layer 120. The water vapor transmission rate of the capping layer 140 may be lower than the water vapor transmission rate of the buffer layer 120.

The capping layer 140 may include, for example, at least one of silicon nitride (SiN), silicon oxynitride (SiON), or silicon oxide (SiO₂), but the technical idea of the present disclosure is not limited thereto.

In some embodiments, the capping layer 140 may include a first capping layer 141 and a second capping layer 142.

The first capping layer 141 may be disposed on the base layer 110, the buffer layer 120, and the debonding layer 130. The first capping layer 141 may extend along the upper surface of the base layer 110, the side wall of the buffer layer 120, and the side wall and upper surface of the debonding layer 130.

The first capping layer 141 may cover the upper surface and side wall of the debonding layer 130. The first capping layer 141 may be in contact with the upper surface and side wall of the debonding layer 130. The first capping layer 141 may cover the side wall of the buffer layer 120. The first capping layer 141 may be in contact with the side wall of the buffer layer 120. The first capping layer 141 may be in contact with the upper surface of the base layer 110.

A width W21 of the first capping layer 141 in the first direction D1 may be greater than a width of the buffer layer 120 in the first direction D1. The width W21 of the first capping layer 141 in the first direction D1 may be greater than the width W1 of the debonding layer 130 in the first direction D1.

The first capping layer 141 may include a first portion 141a and a second portion 141b. The first portion 141a of the first capping layer 141 may be disposed on a side wall of the buffer layer 120 and a side wall of the debonding layer 130. The first portion 141a of the first capping layer 141 may be in contact with the side wall of the buffer layer 120 and the side wall of the debonding layer 130. The first portion 141a of the first capping layer 141 may be in contact with the upper surface of the base layer 110.

The second portion 141b of the first capping layer 141 may be disposed on the upper surface of the debonding layer 130. The second portion 141b of the first capping layer 141 may be in contact with the upper surface of the debonding layer 130. The second portion 141b of the first capping layer 141 may be directly connected to the first portion 141a of the first capping layer 141. The first portion 141a of the first capping layer 141 may be disposed between the base layer 110 and the second portion 141b of the first capping layer 141.

The second capping layer 142 may be disposed on the first capping layer 141. The second capping layer 142 may extend along the profile of the first capping layer 141. The second capping layer 142 may cover the upper surface and side walls of the first capping layer 141. The second capping layer 142 may be in contact with the upper surface and side walls of the first capping layer 141.

A width W22 of the second capping layer 142 in the first direction D1 may be greater than the width W21 of the first capping layer 141 in the first direction D1. The width W22 of the second capping layer 142 in the first direction D1 may be a width W2 of the capping layer 140 in the first direction D1.

The second capping layer 142 may include a first portion 142a and a second portion 142b. The first portion 142a of the second capping layer 142 may be disposed on a side wall of the first capping layer 141. The first portion 142a of the second capping layer 142 may be in contact with the side wall of the first capping layer 141. The first portion 142a of the second capping layer 142 may be in contact with the upper surface of the base layer 110.

The second portion 142b of the second capping layer 142 may be disposed on the upper surface of the first capping layer 141. The second portion 142b of the second capping layer 142 may be in contact with the upper surface of the first capping layer 141. The second portion 142b of the second capping layer 142 may be directly connected to the first portion 142a of the second capping layer 142. The first portion 142a of the second capping layer 142 may be disposed between the base layer 110 and the second portion 142b of the second capping layer 142.

The first capping layer 141 and the second capping layer 142 may include different materials from each other. The oxygen permeability and water vapor permeability of the material included in the first capping layer 141 may be different from the oxygen permeability and water vapor permeability of the material included in the second capping layer 142.

In one or more embodiments, the oxygen permeability and water vapor permeability of the material included in the first capping layer 141 may be lower than the oxygen permeability and water vapor permeability of the material included in the second capping layer 142. For example, the first capping layer 141 may include silicon nitride (SiN), and the second capping layer 142 may include silicon oxynitride (SiON).

In one or more embodiments, the oxygen permeability and water vapor permeability of the material included in the first capping layer 141 may be greater than the oxygen permeability and water vapor permeability of the material included in the second capping layer 142.

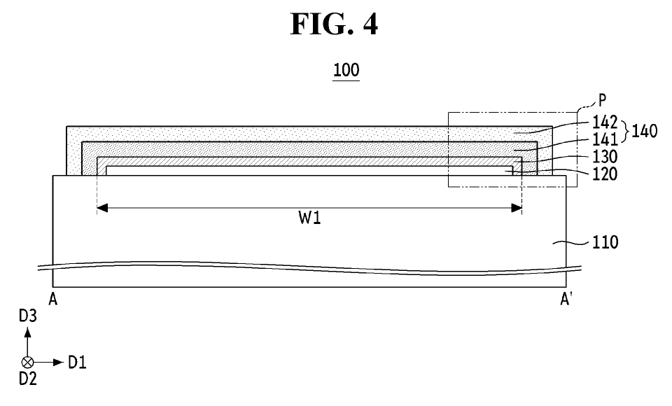

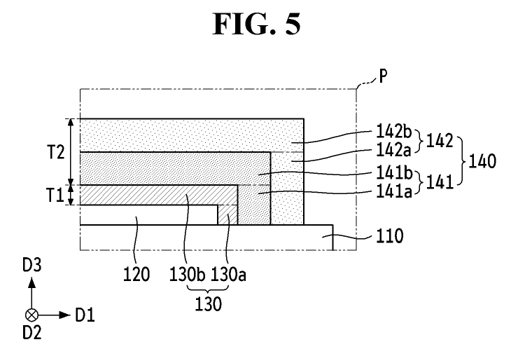

FIGS. 4 - 5 are diagrams for explaining a carrier substrate according to one or more embodiments. For reference, FIG. 4 is a cross-sectional view taken along A-A’ of FIG. 1. FIG. 5 is an enlarged view of a region P of FIG. 4. For convenience of explanation, differences from the above description may be mainly described using FIGS. 1 - 3.

Referring to FIGS. 4 - 5, in one or more embodiments, the buffer layer 120 may be surrounded by the base layer 110 and the debonding layer 130.

The debonding layer 130 may be disposed on the base layer 110 and the buffer layer 120. The debonding layer 130 may extend along the upper surface of the base layer 110, the side walls and the upper surface of the buffer layer 120.

The debonding layer 130 may cover the upper surface and the side walls of the buffer layer 120. The debonding layer 130 may be in contact with the upper surface and the side walls of the buffer layer 120. The debonding layer 130 may be in contact with the upper surface of the base layer 110.

The debonding layer 130 may include a first portion 130a and a second portion 130b. The first portion 130a of the debonding layer 130 may be disposed on the side wall of the buffer layer 120. The first portion 130a of the debonding layer 130 may be in contact with the side wall of the buffer layer 120. The first portion 130a of the debonding layer 130 may be in contact with the upper surface of the base layer 110.

The second portion 130b of the debonding layer 130 may be disposed on the upper surface of the buffer layer 120. The second portion 130b of the debonding layer 130 may be in contact with the upper surface of the buffer layer 120. The second portion 130b of the debonding layer 130 may be directly connected to the first portion 130a of the debonding layer 130. The first portion 130a of the debonding layer 130 may be disposed between the base layer 110 and the second portion 130b of the debonding layer 130.

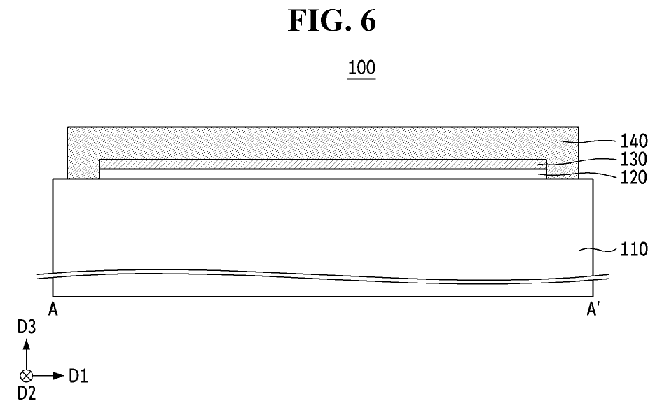

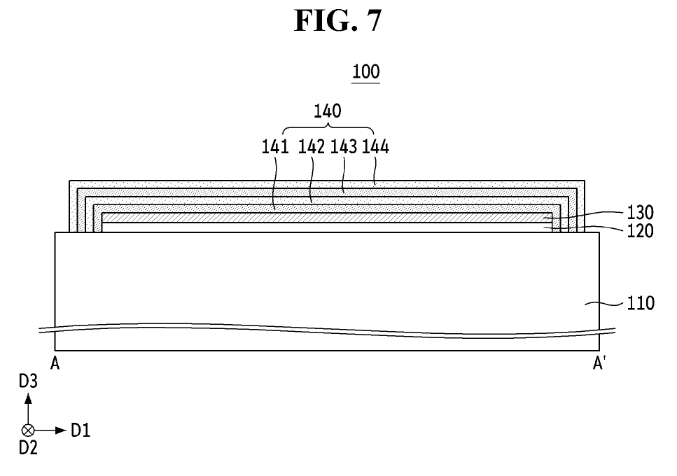

FIG. 6 is a diagram for explaining a carrier substrate according to one or more embodiments. FIG. 7 is a diagram for explaining a carrier substrate according to one or more embodiments. FIGS. 6 and 7 are cross-sectional views taken along line A-A’ of FIG. 1, respectively. For convenience of explanation, differences from the contents explained above using FIGS. 1 - 3 may be mainly described.

Referring to FIG. 6, in one or more embodiments, the capping layer 140 may be a single film.

Referring to FIG. 7, in one or more embodiments, the capping layer 140 may further comprise a third capping layer 143 and a fourth capping layer 144.

The third capping layer 143 may be disposed on the second capping layer 142. The fourth capping layer 144 may be disposed on the third capping layer 143. That is, the first to fourth capping layers 141, 142, 143, and 144 may be sequentially stacked on the base layer 110 and the debonding layer 130.

The third capping layer 143 may include the same material as the first capping layer 141. For example, the third capping layer 143 and the first capping layer 141 may include silicon nitride (SiN).

The fourth capping layer 144 may include the same material as the second capping layer 142. For example, the fourth capping layer 144 and the second capping layer 142 may include silicon oxynitride (SiON).

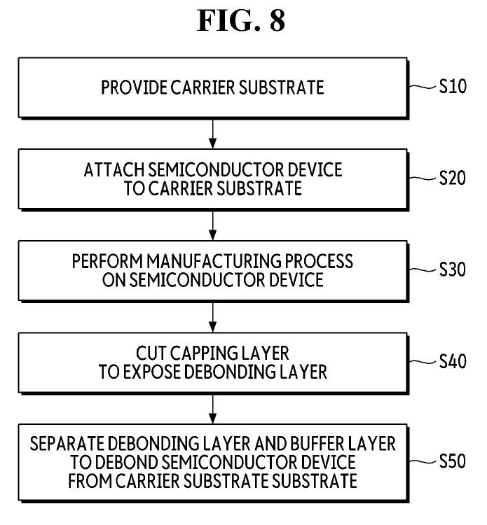

Hereinafter, embodiments of a method for manufacturing a semiconductor device using a carrier substrate according to the technical idea of the present disclosure may be described referring to FIGS. 8 - 16.

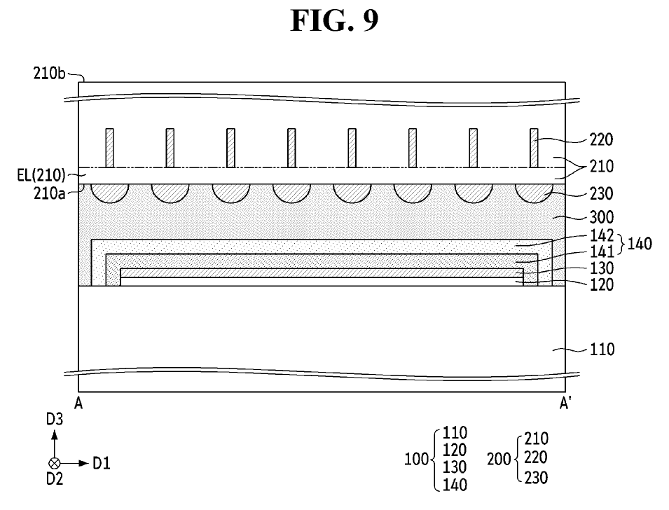

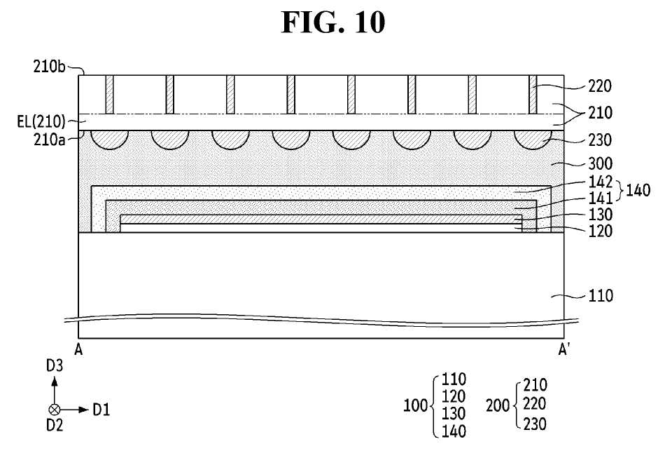

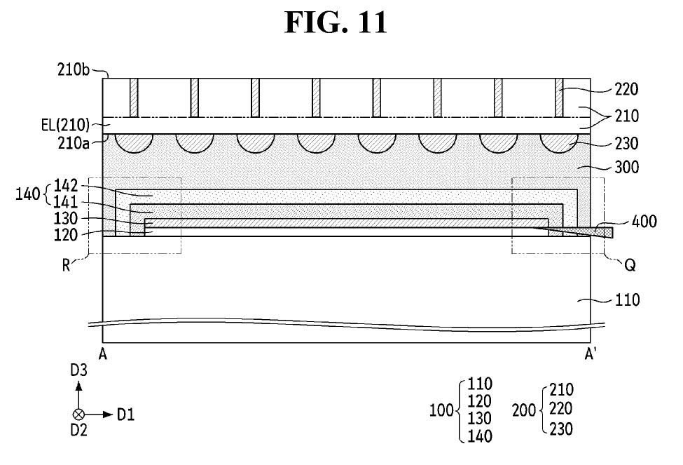

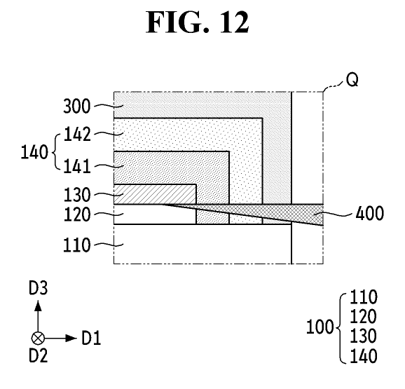

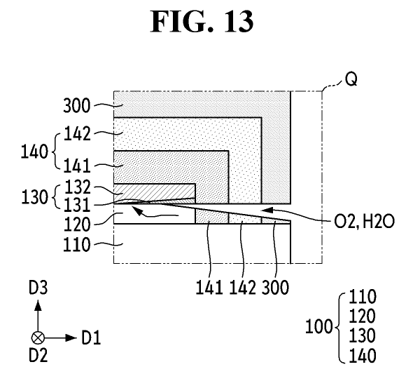

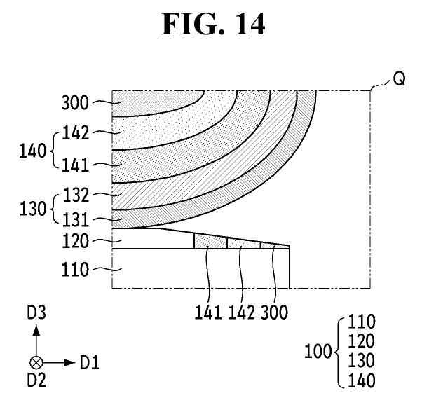

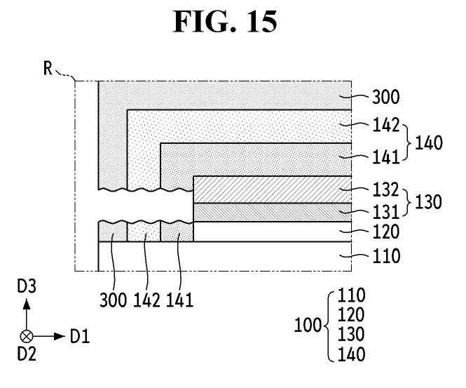

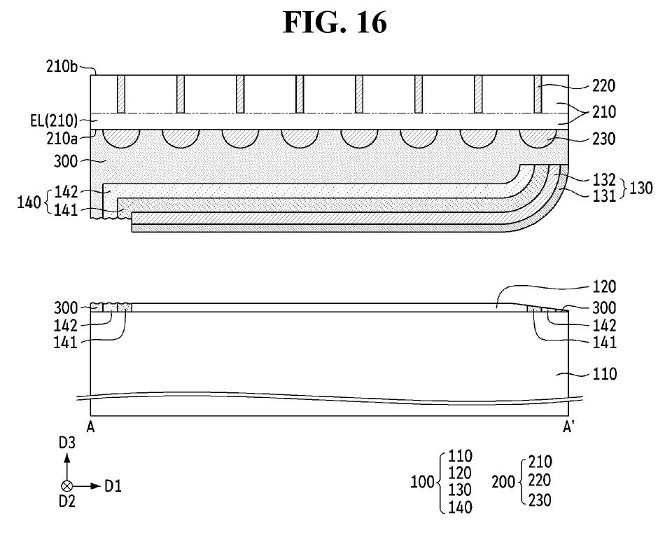

FIG. 8 is a flowchart for explaining the method for manufacturing a semiconductor device using a carrier substrate according to one or more embodiments. FIGS. 9 - 16 are intermediate step diagrams for explaining the method for manufacturing the semiconductor device using the carrier substrate of FIG. 8. For convenience of description, the contents explained above using FIGS. 1 - 7 may be briefly described or omitted.

Referring to FIGS. 8 and 9, a carrier substrate 100 is provided (S10), and a semiconductor device 200 is attached to the carrier substrate 100 (S20).

In one or more embodiments, the semiconductor device 200 (i.e., a semiconductor or integrated circuit (IC) component, element, feature, etc.) may include a device wafer 210, a plurality of through vias 220, and a connecting member 230.

The device wafer 210 may have a disk shape. The device wafer 210 may include a silicon wafer, chip, die, substrate, etc. For example, the device wafer 210 may include a compound semiconductor such as SOI (Silicon On Insulator), silicon-germanium, silicon-carbide or gallium-arsenide, but the material is not particularly limited thereto. A width of the device wafer 210 in the first direction D1 may be equal to a width of the base layer 110 in the first direction D1.

The device wafer 210 may include a first surface 210a and a second surface 210b that are opposite to each other in the third direction D3. The device wafer 210 may include an element layer CL. The element layer CL may be closer to the first surface 210a of the device wafer 210 than the second surface 210b of the device wafer 210. The element layer CL may include a plurality of individual elements that constitute an integrated circuit. Each individual element may include at least one of a field-effect transistor (FET) such as a planar FET, a FinFET, and a Multi-Bridge-Channel FET (MBCFET); a memory element such as a flash memory, a Dynamic Random Access Memory (DRAM), a Static Random Access Memory (SRAM), an Electrically Erasable Programmable Read-Only Memory (EEPROM), a Parallel Random Access Memory (PRAM), Phase Change Memory (PCM), a Magnetoresistive Random Access Memory (MRAM), a Ferroelectric Random Access Memory (FeRAM), and a Resistive Random Access Memory (RRAM); a logic element such as an AND, an OR and a NOT device and/or gate; and various active and passive elements such as a system Large Scale Integration (LSI), a Complementary Metal-Oxide-Semiconductor (CMOS) Image Sensor (CIS), and a Micro-Electro-Mechanical Systems (MEMS).

A plurality of through vias 220 may be disposed inside the device wafer 210. The plurality of through vias 220 may be spaced apart from one another. Each through via 220 may be physically and electrically connected to the element layer CL. Each through via 220 may extend from the element layer CL toward the second surface 210b of the device wafer 210. The through vias 220 may include a conductive material. For example, the through vias 220 may include Ag, Au, Cu, W, Al or In. The through vias 220 may be through silicon vias (TSV).

The connecting member 230 may be attached onto the first surface 210a of the device wafer 210. The connecting member 230 may have a shape such as a land, a ball, and a pin. The connecting member 230 may be electrically connected to the element layer CL. The element layer CL may transmit and receive signals to and from the outside through the connecting member 230.

The connecting member 230 may include a conductive material. For example, the connecting member 230 may include tin (Sn) or an alloy containing tin (Sn). The connecting member 230 may be a solder ball or a bump.

In one or more embodiments, unlike those shown in the drawings, the semiconductor device 200 may be at least one of a silicon substrate, a glass substrate, an organic substrate, or a ceramic substrate.

The semiconductor device 200 may be attached to the carrier substrate 100, using an adhesive 300. Specifically, the adhesive 300 may be applied to the semiconductor device 200 first. The adhesive may include, for example, epoxy resin, benzocyclobutene (BCB), or polyimide (PI), but is not limited thereto and any suitable adhesive may be used. The adhesive 300 may cover the first surface 210a of the device wafer 210 and the connecting member 230. The semiconductor device 200 may then be attached to the carrier substrate 100 such that the adhesive 300 faces the carrier substrate 100.

Referring to FIGS. 8 and 10, a manufacturing process on the semiconductor device 200 is performed (S30).

In one or more embodiments, the manufacturing process on the semiconductor device 200 may be a thinning process for thinning the thickness of the semiconductor device 200. The thinning process may be performed on the second surface 210b of the device wafer 210. As the thinning process is performed, a part of the device wafer 210 is removed, and the thickness of the device wafer 210 in the third direction D3 may decrease.

The thinning process may be performed to expose the through vias 220. As the thinning process is performed, a part of the device wafer 210 is removed, and the upper surface of the through via 220 may be exposed. The upper surface of the through via 220 and the second surface 210b of the device wafer 210 may be coplanar with each other.

The thinning process may be performed through grinding, chemical mechanical polishing (CMP), wet etching, dry etching or a combination thereof.

Unlike the shown example, in one or more embodiments, the manufacturing process on the semiconductor device 200 may include a process of forming a redistribution layer for interconnecting a plurality of semiconductor chips mounted on and within the semiconductor device 200.

Referring to FIGS. 8 and 11 - 15, the capping layer 140 is cut to expose the debonding layer 130 (S40). For reference, FIGS. 12 - 14 are enlarged views of a region Q of FIG. 11. FIG. 15 is an enlarged view of a region R of FIG. 11.

First, referring to FIGS. 11 and 12, a blade 400 is inserted into the capping layer 140. The blade 400 may reach the buffer layer 120 and/or the debonding layer 130 beyond the capping layer 140. The blade 400 may have a wedge shape, and may be made of a high-hardness metal such as stainless steel or tungsten carbide, but the material is not limited thereto and any suitable blade may be used. The blade 400 may be inserted in a direction parallel to the upper surface of the base layer 110. The blade 400 may be inserted through the side wall of the capping layer 140. As the blade 400 is inserted, the capping layer 140 may be cut.

Next, referring to FIGS. 13 - 14, the buffer layer 120 and/or the debonding layer 130 may be exposed to the external or ambient environment through a gap formed by the cutting of the capping layer 140. The exposed debonding layer 130 may react with external oxygen and water vapor from the external environment, and may be at least partially oxidized. Water vapor reacting with the debonding layer 130 may promote the oxidation of the debonding layer 130.

The buffer layer 120 may further promote the oxidation of the debonding layer 130. Specifically, since the buffer layer 120 has high oxygen transmission rate and high water vapor transmission rate, external oxygen and water vapor may pass through the buffer layer 120 and react with the debonding layer 130 through an interface between the buffer layer 120 and the debonding layer 130.

The debonding layer 130 may expand by oxidation. Specifically, as at least a part of the debonding layer 130 is oxidized, the at least partially oxidized debonding layer 130 may include a metal layer 131 and a metal oxide layer 132. The metal oxide layer 132 may be disposed between the buffer layer 120 and the metal layer 131. The sum of the thickness of the metal layer 131 and the thickness of the metal oxide layer 132 may be greater than the thickness of the debonding layer 130 before exposed to the outside.

The metal layer 131 may include a metal having a Pilling-Bedworth ratio (PBR) of 1.2 or more and 10 or less. The metal oxide layer 132 may include an oxide of the metal included in the metal layer 131. For example, when the metal layer 131 includes aluminum (Al), the metal oxide layer 132 may include aluminum oxide (Al₂O₃).

Since oxidation of the debonding layer 130 may progress from the exposed portion, the debonding layer 130 may expand preferentially in the region adjacent to the portion in which the capping layer 140 is cut. Due to the expansion, the debonding layer 130 may warp toward the semiconductor device 200, and therefore, the capping layer 140 may also warp toward the semiconductor device 200 together with the debonding layer 130. Accordingly, the gap formed by the cutting of the capping layer 140 may gradually widen.

Meanwhile, referring to FIG. 15, due to the expansion of the debonding layer 130, cracks may also occur in the uncut portion of the capping layer 140. Accordingly, the capping layer 140 may be separated from the base layer 110.

Next, referring to FIGS. 8 and 16, the debonding layer 130 and the buffer layer 120 may be separated to debond the semiconductor device 200 from the carrier substrate 100 (S50).

First, a clamping device may clamp the debonding layer 130 and the semiconductor device 200 together. The clamping device may support the warped portion of the debonding layer 130. As the debonding layer 130 warps toward the semiconductor device 200, and as the gap formed by the cutting of the capping layer 140 widens, the clamping device may more easily clamp the debonding layer 130 and the semiconductor device 200.

The clamping device may then lift the debonding layer 130 and the semiconductor device 200 together. As the clamping device lifts the debonding layer 130, the debonding layer 130 may be separated from the buffer layer 120. Because the adhesive force between the debonding layer 130 and the buffer layer 120 may be relatively low, the debonding layer 130 may be easily separated from the buffer layer 120. As the debonding layer 130 is separated from the buffer layer 120, the semiconductor device 200 may be debonded from the carrier substrate 100.

The carrier substrate 100 of the present disclosure may include the buffer layer 120 and the debonding layer 130 formed on the base layer 110 (which may be a silicon wafer), and the capping layer 140 that caps the buffer layer 120 and the debonding layer 130.

The buffer layer 120 of the present disclosure may be made of a material that has low shear adhesive force to the debonding layer 130. Accordingly, the debonding layer 130 may be easily separated from the buffer layer 120 in the process of debonding the semiconductor device 200 from the carrier substrate 100.

The debonding layer 130 of the present disclosure may also be made of a material that expands in volume when oxidized. The capping layer 140 may be made of a material with low oxygen permeability to prevent the debonding layer 130 from being oxidized before performing the debonding process. Therefore, when the capping layer 140 is cut to expose the debonding layer 130 to the outside, the debonding layer 130 may expand due to an oxidation reaction, causing cracks to form throughout the capping layer 140, through which the capping layer 140 may be easily separated from the base layer 110. That is, the capping layer 140 may be separated from the base layer 110 even if only a part of the capping layer 140 is cut. In this process, the buffer layer 120 is designed to have high oxygen transmission rate, and therefore may promote oxidation of the debonding layer 130.

In addition, the debonding layer 130 may warp or bend toward the semiconductor device 200 in the oxidation expansion process of the debonding layer 130. As a result, as the gap formed by the cutting of the capping layer 140 widens, the debonding layer 130 may be more easily separated from the buffer layer 120.

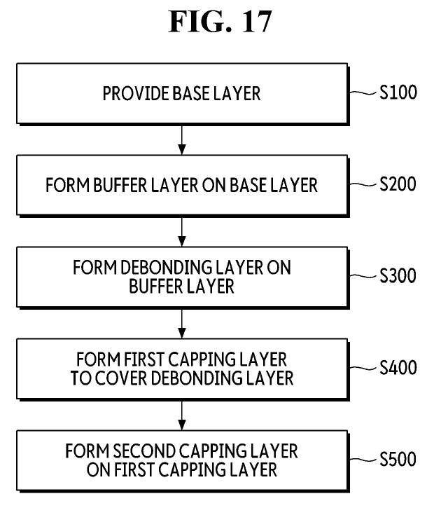

Hereinafter, one or more embodiments of the method for manufacturing the carrier substrate according to the technical idea of the present disclosure may be described referring to FIGS. 17 - 21.

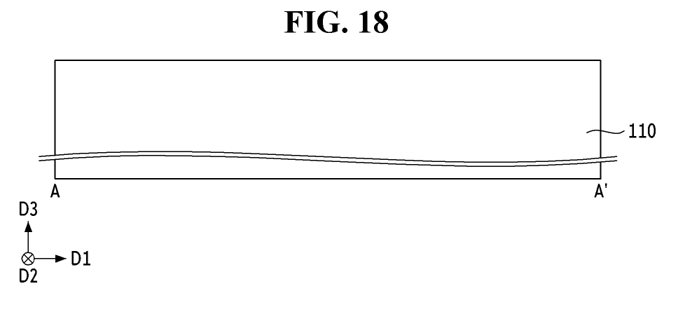

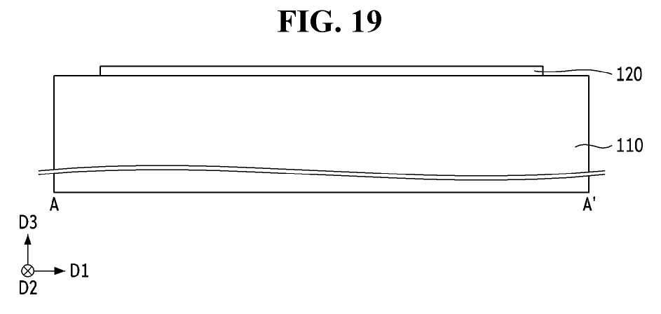

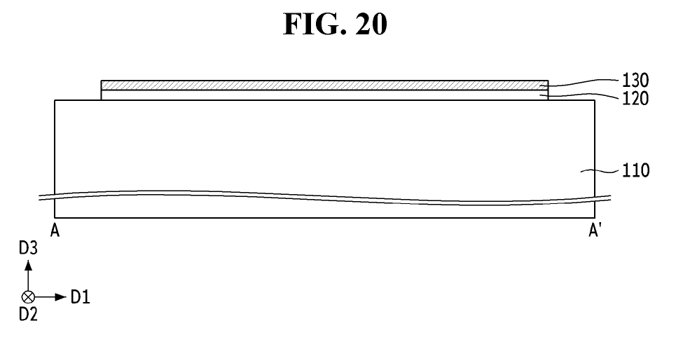

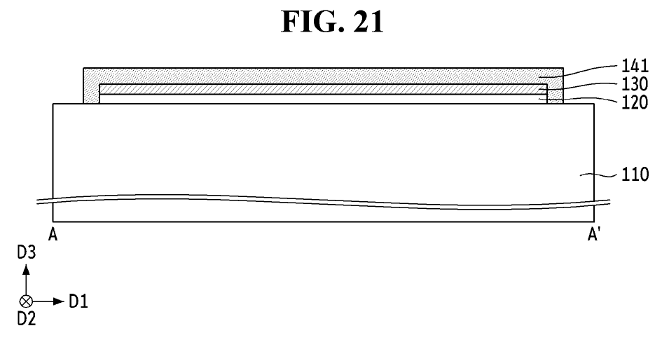

FIG. 17 is a flowchart for explaining a method for manufacturing the carrier substrate according to one or more embodiments. FIGS. 18 - 21 are intermediate step diagrams for explaining a method for manufacturing the carrier substrate of FIG. 17. For convenience of explanation, repeated parts of contents explained above using FIGS. 1 - 7 may be briefly explained or omitted.

Referring to FIGS. 17 and 18, a base layer 110 is provided (S100). The base layer 110 may be a silicon wafer, chip, die, substrate, etc., and may comprise other materials besides or in addition to silicon.

Referring to FIGS. 17 and 19, a buffer layer 120 may be formed on the base layer 110 (S200).

The buffer layer 120 may be formed on the upper surface of the base layer 110. The buffer layer 120 may be formed to cover at least a part of the upper surface of the base layer 110. The buffer layer 120 may be formed to cover the upper surface of the base layer 110 except for an edge thereof.

The buffer layer 120 may be formed through a deposition process. For example, the buffer layer 120 may be formed using atomic layer deposition (ALD). The buffer layer 120 may include an organic material.

Referring to FIGS. 17 and 20, the debonding layer 130 is formed on the buffer layer 120 (S300).

The debonding layer 130 may be formed on the upper surface of the buffer layer 120. The debonding layer 130 may be formed to cover the upper surface of the buffer layer 120. In one or more embodiments, the debonding layer 130 may be formed to cover the upper surface and side walls of the buffer layer 120.

The debonding layer 130 may be formed through a deposition process. For example, the debonding layer 130 may be formed using a sputtering technique, vapor deposition process, and/or any other suitable deposition process. The debonding layer 130 may include a metal.

Referring to FIGS. 17 and 21, a first capping layer 141 is formed to cover the debonding layer 130 (S400).

The first capping layer 141 may be formed on the base layer 110 and the debonding layer 130. The first capping layer 141 may be formed on the upper surface of the base layer 110 on which the buffer layer 120 and the debonding layer 130 are not formed. The first capping layer 141 may be formed to cover the side wall of the buffer layer 120 and the side wall and upper surface of the debonding layer 130. As the first capping layer 141 is formed, the buffer layer 120 and the debonding layer 130 may be sealed by the base layer 110 and the first capping layer 141.

The first capping layer 141 may be formed to be thicker than the buffer layer 120. The first capping layer 141 may be formed to be thicker than the debonding layer 130.

The first capping layer 141 may be formed through a deposition process. For example, the first capping layer 141 may be formed using a chemical vapor deposition (CVD) method.

The first capping layer 141 may include at least one of silicon nitride (SiN), silicon oxynitride (SiON) or silicon oxide (SiO₂), but the technical idea of the present disclosure is not limited thereto.

Referring to FIGS. 17 and 2, a second capping layer 142 is formed on the first capping layer 141 (S500).

The second capping layer 142 may be formed along a profile of the first capping layer 141. The second capping layer 142 may be formed to cover the upper surface and side walls of the first capping layer 141.

The second capping layer 142 may be formed through a deposition process. For example, the second capping layer 142 may be formed using a chemical vapor deposition (CVD) method.

The second capping layer 142 may include at least one of silicon nitride (SiN), silicon oxynitride (SiON) or silicon oxide (SiO₂), but the technical idea of the present disclosure is not limited thereto.

The second capping layer 142 may include a material different from that included in the first capping layer 141. For example, the first capping layer 141 may include silicon nitride (SiN), and the second capping layer 142 may include silicon oxynitride (SiON).

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A carrier substrate comprising:
a base layer;
a buffer layer on the base layer;
a debonding layer on the buffer layer and comprising a metal; and
a capping layer on the debonding layer and in contact with an upper surface of the base layer,
wherein an oxygen transmission rate (OTR) of the buffer layer is greater than an OTR of the capping layer.

2. The carrier substrate of claim 1, wherein the buffer layer is surrounded by the base layer and the capping layer and/or the debonding layer is surrounded by the base layer and the capping layer.

3. The carrier substrate of claim 1, wherein the capping layer is in contact with an upper surface and a side wall of the debonding layer.

4. The carrier substrate of claim 1, wherein the capping layer comprises a first capping layer on the debonding layer, and a second capping layer on the first capping layer.

5. The carrier substrate of claim 4, wherein the first capping layer comprises a first portion on a side wall of the debonding layer and in contact with the upper surface of the base layer, and a second portion on an upper surface of the debonding layer and connected to the first portion.

6. The carrier substrate of claim 4, wherein an oxygen permeability (OP) of a material of the first capping layer is different from an OP of a material of the second capping layer.

7. The carrier substrate of claim 1, wherein the OTR of the capping layer is 10⁻² cc/m²·day or less.

8. The carrier substrate of claim 1, wherein the base layer comprises single crystal silicon (Si).

9. The carrier substrate of claim 4, wherein the capping layer further comprises a third capping layer on the second capping layer and comprises a same material as the first capping layer.

10. The carrier substrate of claim 9, wherein the capping layer further comprises a fourth capping layer on the third capping layer and comprises a same material as the second capping layer.

11. The carrier substrate of claim 1, wherein a Pilling-Bedworth ratio (PBR) of the metal of the debonding layer is 1.2 or more.

12. The carrier substrate of claim 1, wherein the OTR of the buffer layer is 20 cc/m²·day or more.

13. The carrier substrate of claim 12, wherein the buffer layer is in contact with a bottom surface of the debonding layer, and a shear adhesion strength between the buffer layer and the debonding layer is 1 MPa or less.

14. A carrier substrate comprising:
a base layer comprising single crystal silicon (Si);
an organic layer on the base layer and having an oxygen transmission rate (OTR) of 20 cc/m²·day or more;
a metal layer on the organic layer and having a Pilling-Bedworth ratio (PBR) of 1.2 or more; and
a capping layer on the metal layer and comprising a first capping layer in contact with an upper surface of the base layer and a side wall of the metal layer, and a second capping layer on the first capping layer,
wherein an OTR of the capping layer is 10⁻² cc/m²·day or less, and
an oxygen permeability (OP) of a material of the first capping layer is different from an OP of a material of the second capping layer.

15. The carrier substrate of claim 14, wherein the first capping layer comprises a first portion on the side wall of the metal layer and in contact with the base layer, and a second portion on an upper surface of the metal layer and connected to the first portion.

16. The carrier substrate of claim 14, wherein the organic layer is in contact with a bottom surface of the metal layer, and a shear adhesion strength between the organic layer and the metal layer is 1 MPa or less.

17. A method for manufacturing a semiconductor device, the method comprising:
providing a carrier substrate comprising a base layer, a buffer layer on the base layer, a debonding layer on the buffer layer and comprising a metal, and a capping layer on the debonding layer and in contact with an upper surface of the base layer, wherein the debonding layer is surrounded by the base layer and the capping layer, and an oxygen transmission rate (OTR) of the buffer layer is greater than an OTR of the capping layer;
attaching a semiconductor component onto the carrier substrate;
cutting a part of the capping layer to expose the debonding layer to an external environment; and
separating the debonding layer and the buffer layer to debond the semiconductor device from the carrier substrate.

18. The method for manufacturing the semiconductor device of claim 17, wherein the capping layer is in contact with an upper surface and a side wall of the debonding layer.

19. The method for manufacturing the semiconductor device of claim 17, wherein an OTR of the capping layer is 10⁻² cc/m²·day or less.

20. The method for manufacturing the semiconductor device of claim 17, wherein the base layer comprises single crystal silicon (Si).
